(19) United States
(12) Patent Application Publication
(10) Pub. No.: US 2022/0048152 A1
(43) Pub. Date: Feb. 17, 2022

(54) PROCESSING APPARATUS

(71) Applicant: Disco Corporation, Tokyo (JP)

(72) Inventor: Mato HATTORI, Tokyo (JP)

(21) Appl. No.: 17/389,764

(22) Filed: Jul. 30, 2021

(30) Foreign Application Priority Data
Aug. 17, 2020 (JP) 2020-137424

(51) Int. Cl. B24B 7/22; B24B 41/04

(52) U.S. Cl. CPC B24B 7/228; B24B 41/04

(57) ABSTRACT

A spindle unit mounted to a processing unit has a collar section extending from an outside surface of the spindle unit in a horizontal direction. The processing unit includes a bottom plate having a through-hole through which a lower portion of the spindle unit penetrates, a holder including a side plate that surrounds the spindle unit with the collar section supported by the bottom plate and that is connected to the bottom plate, and an inclination adjusting mechanism that acts on the collar section to adjust the inclination of the spindle unit. The inclination adjusting mechanism includes a spring interposed between a lower surface of the collar section and an upper surface of the bottom plate and an adjusting section that acts to compress the spring and adjusts the inclination of the spindle unit by a compression amount of the spring.

### BACKGROUND OF THE INVENTION

### Field of the Invention

The present invention relates to a processing apparatus for processing a workpiece such as a semiconductor wafer.

### Description of the Related Art

For example, a grinding apparatus in which a spindle unit supporting a spindle in a rotatable manner with an annular grindstone mounted to a tip thereof is lifted upward and downward to grind a wafer held by a holding surface of a turntable includes an inclination adjusting mechanism capable of adjusting an inclination of a chuck table for adjusting parallelism between a lower surface of the grindstone and the holding surface holding the wafer (see, for example, Japanese Patent Laid-open No. Hei 08-090376 and Japanese Patent Laid-open No. 2002-001653).

### SUMMARY OF THE INVENTION

The processing apparatus having a plurality of chuck tables disposed on a turntable includes the inclination adjusting mechanisms for the chuck tables as described above. The inclination adjusting mechanism changes the inclination of the holding surface by changing the distance between an upper surface of the turntable and a lower surface of the chuck table. Specifically, a column that is disposed on the turntable and that extends in the vertical direction is formed with a screw, and a motor for rotating the screw to move the column upward and downward is disposed under the turntable. The turntable is thus formed with a recess or a through-hole for disposing the inclination adjusting mechanism.

Being formed with the recess or through-hole, the turntable is lowered in rigidity. In the case of grinding a wafer under a high load, the turntable is liable to warp under the load. As a result, there occurs a problem that the accuracy of thickness in plane of the wafer is worsened. Therefore, in the processing apparatus, at the time of grinding the wafer under a high load, the turntable or the like on which the chuck tables are to be disposed should be prevented from warping.

In accordance with an aspect of the present invention, there is provided a processing apparatus including a processing unit in which a spindle unit supporting, in a rotatable manner, a spindle having a processing tool mounted to a tip thereof and extending in a vertical direction is mounted; and a chuck table that holds a workpiece. In the processing apparatus, the spindle unit has a collar section extending from an outside surface in a horizontal direction orthogonal to the outside surface, the processing unit includes a holder including a bottom plate having a through-hole through which a lower portion of the spindle unit penetrates and a side plate that surrounds the spindle unit with the collar section supported by the bottom plate and that is connected to the bottom plate, and an inclination adjusting mechanism that acts on the collar section to adjust an inclination of the spindle unit, and the inclination adjusting mechanism includes a spring interposed between a lower surface of the collar section and an upper surface of the bottom plate and an adjusting section that acts to compress the spring and adjusts the inclination of the spindle unit by a compression amount of the spring.

Preferably, the adjusting section includes a female screw formed in the bottom plate, a shaft having a male screw for screw engagement with the female screw on a lower end side and having a flange on an upper end side, a motor that rotates the shaft, and a threaded through-hole that is formed in the collar section and permits the shaft to penetrate therethrough, and the processing apparatus includes a bearing that supports, in a rotatable manner, the flange of the shaft penetrating the threaded through-hole in the collar section and having the male screw in screw engagement with the female screw, by an upper surface of the collar section.

Preferably, the adjusting section includes a support plate that is disposed on an inner wall of the side plate and that has a support surface facing the upper surface of the collar section; and a piezoelectric actuator disposed between the support surface and the upper surface of the collar section.

According to the present invention, the inclination adjusting mechanism includes the spring interposed between the lower surface of the collar section and the upper surface of the bottom plate and the adjusting section that acts to compress the spring and that adjusts the inclination of the spindle unit by the compression amount of the spring, whereby the need to change the inclination of the chuck table is eliminated, and the need to form the turntable or the table base with a cavity for disposing the inclination adjusting mechanism is eliminated. Thus, when the wafer is processed under a high load, the turntable on which the chuck table is disposed or the table base is not liable to warp, making it possible to process the wafer flat. In addition, with the weight of the processing unit received by the spring, it becomes possible to reduce the sizes of the motor as a drive source for rotating the shaft, the motor as a drive source for rotating the spindle, and the like.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting an example of a processing apparatus;

FIG. 2 is a sectional view depicting a structure of a rough grinding unit to which a holding unit and a spindle unit are mounted;

FIG. 3 is a sectional view depicting, in an enlarged from, a structure of an inclination adjusting mechanism including an adjusting section according to a first embodiment; and

FIG. 4 is a sectional view depicting a rough grinding unit including an inclination adjusting mechanism that includes an adjusting section according to a second embodiment.

### DETAILED DESCRIPTION OF THE PREFERRED EMBODIMENTS

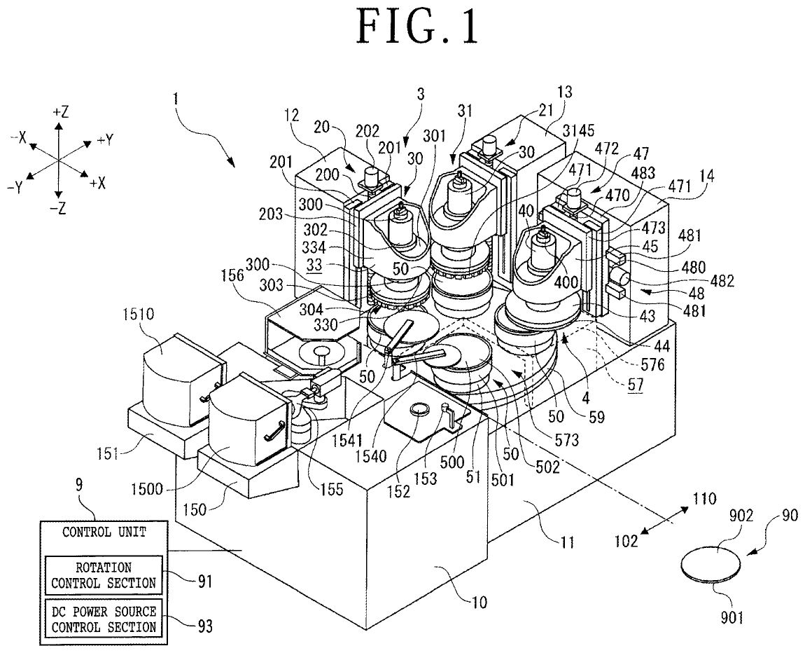

A processing apparatus 1 illustrated in FIG. 1 is an apparatus which includes, for example, a rough grinding unit 3, a finish grinding unit 31, and a polishing unit 4, which grinds a workpiece 90 held on a holding unit 50 being any of chuck tables revolved by a turntable 59 by the rough grinding unit 3 and the finish grinding unit 31, and which polishes the workpiece 90 by the polishing unit 4. Note that the processing apparatus according to the present invention may be configured to grind or polish the workpiece 90 held by the chuck table rectilinearly moved in a Y-axis direction, by a uniaxial grinding unit or a uniaxial polishing unit.

The processing apparatus 1 has, for example, a second apparatus base 11 connected to a rear side (+Y direction side) of a first apparatus base 10. An upper side of the first apparatus base 10 is a conveying-in/out region 102 where conveying-in/out from a cassette, centering, cleaning, and the like of the workpiece 90 are conducted, and an upper side of the second apparatus base 11 is a processing region 110 where the workpiece 90 held by the holding unit 50 is processed by the rough grinding unit 3, the finish grinding unit 31, or the polishing unit 4.

The workpiece 90 depicted in FIG. 1 is, for example, a disk-shaped semiconductor wafer formed of a silicon base material or the like, and a front surface 901 of the workpiece 90 directed downward in FIG. 1 is formed with a plurality of devices, and has an unillustrated protective tape attached thereto and is thereby protected. A back surface 902 of the workpiece 90 directed to the upper side is a work surface to be ground and polished.

On a front side (−Y direction side) of the first apparatus base 10, there are provided a first cassette mount section 150 and a second cassette mount section 151, a first cassette 1500 accommodating the workpieces 90 yet to be processed is mounted on the first cassette mount section 150, and a second cassette 1510 accommodating the workpieces 90 that have been processed is mounted on the second cassette mount section 151.

On a rear side of an opening of the first cassette 1500, disposed is an articulated robot 155 which conveys out the workpiece 90 yet to be processed from the first cassette 1500 and conveys in the workpiece 90 that has been processed into the second cassette 1510.

A temporary placing region 152 is provided at a position adjacent to the robot 155, and center position detecting means 153 is disposed in the temporary placing region 152. The center position detecting means 153 images the workpiece 90 conveyed out from the first cassette 1500 and mounted on the temporary placing region 152, and detects the center position of the workpiece 90 by image analysis of the picked-up image.

In the example depicted in FIG. 1, at a position adjacent to the center position detecting means 153, a loading arm 1540 that slews in a state of holding the workpiece 90 is disposed. The loading arm 1540 holds the workpiece 90 aligned by the center position detecting means 153, and conveys the workpiece 90 to the holding unit 50 positioned inside a workpiece conveying-in/out area 573. Adjacent to the loading arm 1540, an unloading arm 1541 that slews in a state of holding the workpiece 90 that has been processed is provided. In a movable range of the unloading arm 1541, a single wafer cleaning unit 156 for cleaning the workpiece 90 that has been processed and then conveyed by the unloading arm 1541 is disposed. The workpiece 90 cleaned by the cleaning unit 156 is conveyed into the second cassette 1510 by the robot 155.

As depicted in FIG. 1, a turntable 59 circular in plan view is disposed on the second apparatus base 11, and a plurality of (for example, four) holding units 50 that are disposed at regular intervals in a circumferential direction of the turntable 59 with the center of the turntable 59 as a center and that have holding surfaces 502 for holding the workpiece 90 are disposed on an upper surface of the turntable 59. Note that the holding units 50 are disposed on a rectilinearly moving base rectilinearly moving in the Y-axis direction.

An unillustrated rotary shaft for rotation of the turntable 59 is connected to the center of the turntable 59, and the rotary shaft whose axial direction is directed in a Z-axis direction is rotatable by a motor. By putting the turntable 59 into rotation with the center of the turntable 59 as an axis, the plurality of (for example, four) holding units 50 holding the workpieces 90 can be put into revolution, and the holding units 50 can be sequentially positioned from the vicinity of the temporary placing region 152 to a lower side of the rough grinding unit 3, a lower side of the finish grinding unit 31, and a lower side of the polishing unit 4. For example, the turntable 59 is floated by air jetted to a lower surface thereof on an upper side of the second apparatus base 11, and is in a rotatable state as described above.

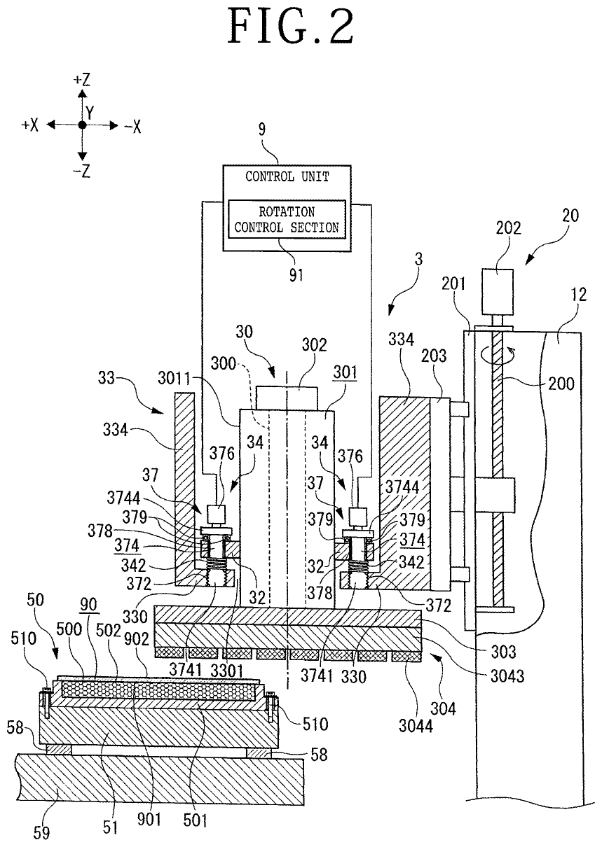

As depicted in FIG. 2, the holding unit 50 includes, for example, a porous plate 500 that is disk-shaped in outer shape and that has a holding surface 502 for holding the workpiece 90 and a frame body 501 having a recess for accommodating the porous plate 500 while exposing the holding surface 502. An unillustrated suction source is connected to the holding surface 502, and a suction force generated by the suction source is transmitted to the holding surface 502. In addition, the holding unit 50 is rotatable with a rotary shaft whose axial direction is in the Z-axis direction as an axis. For example, the holding surface 502 is formed in an extremely gentle conical surface to such an extent as not to be visually distinguishable by the naked eye, with the center of the holding surface 502 as a vertex.

As depicted in FIG. 2, the holding unit 50 is disposed on the turntable 59 in a state of being fixed to a circular table base 51 roughly the same in diameter as the holding unit 50 by bolts 510, and, for example, three (only two are illustrated) load sensors 58 for measuring the load exerted on the workpiece 90 are provided at connection parts between the table base 51 and the turntable 59. In the present embodiment, the three load sensors 58 are in a state of being clamped between the table base 51 and the turntable 59, and are located with 120 degrees spacings in the circumferential direction on a lower surface of the table base 51, or respectively located at the vertexes of an equilateral triangle. The load sensor 58 receives and detects a load exerted from a +Z direction on the holding unit 50 holding the workpiece 90 under suction, or a load exerted on the workpiece 90. The load sensor 58 includes, for example, a thin type force sensor made by Kistler Holding AG which uses, for example, a piezoelectric element such as lead zirconate titanate (PZT).

As illustrated in FIG. 1, the upper side of the turntable 59 and the holding unit 50 is substantially entirely covered with a case cover 57. One corner of the case cover 57 is cut out, for example, in a rectangular shape in plan view, and at the cutout part, the holding surface 502 of the holding unit 50 is exposed to the exterior from the case cover 57 such that the workpiece 90 can be conveyed in and out. The cutout part of the case cover 57 becomes a workpiece conveying-in/out area 573 where the loading arm 1540 can convey in the workpiece 90 into the holding unit 50 and where the unloading arm 1541 can convey out the workpiece 90 from the holding unit 50.

A top plate 576 of the case cover 57 depicted in FIG. 1 is formed with unillustrated three openings in a penetrating manner through which a rough grinding wheel 304 of the rough grinding unit 3, a grinding wheel of the finish grinding unit 31, or a polishing pad 44 of the polishing unit 4 can be passed into the case cover 57.

As illustrated in FIG. 1, a first column 12 is erected on a lateral side (−X direction side) of the second apparatus base 11, and rough grinding feeding means 20 is disposed on a front side of the first column 12. The rough grinding feeding means 20 includes a ball screw 200 having an axis in the vertical direction (Z-axis direction), a pair of guide rails 201 disposed in parallel to the ball screw 200, a motor 202 connected to the ball screw 200 for rotating the ball screw 200, and a lift plate 203 a nut inside of which is in screw engagement with the ball screw 200 and side portions of which are in sliding contact with the guide rails 201.

When the motor 202 rotates the ball screw 200, the lift plate 203 is attendantly moved reciprocally in the Z-axis direction while being guided by the guide rails 201, and the rough grinding unit 3 attached to the lift plate 203 is also reciprocally moved in the Z-axis direction.

The rough grinding unit 3 to which is mounted the spindle unit 30 supporting, in a rotatable manner, the spindle 300 having the rough grinding wheel 304 as a processing tool mounted to a tip (lower end) thereof and extending in the vertical direction will be described below.

The spindle unit 30 depicted in FIGS. 1 and 2 includes the spindle 300 whose axial direction is the vertical direction (Z-axis direction), a housing 301 supporting the spindle 300 in a rotatable manner, a grinding motor 302 driving the spindle 300 in a rotational manner, and the rough grinding wheel 304 detachably connected to a lower surface of a circular mount 303 connected to the lower end of the spindle 300. As depicted in FIG. 2, the rough grinding wheel 304 includes a wheel base 3043 and a plurality of rough grinding grindstones 3044 that have a substantially rectangular parallelepiped shape and that are mounted in an annular pattern on a bottom surface of the wheel base 3043. The rough grinding grindstone 3044 is, for example, a grindstone in which relatively large abrasive grains are contained.

For example, the spindle 300 is formed therein with a grinding water passage extending in the Z-axis direction, and unillustrated grinding water supply means communicates with the grinding water passage. Grinding water supplied from the grinding water supply means to the spindle 300 is jetted downward toward the rough grinding grindstones 3044 from an opening at the lower end of the grinding water passage, to reach contact parts between the rough grinding grindstone 3044 and the workpiece 90.

As illustrated in FIG. 2, the spindle unit 30 includes, for example, a collar section 32 in an annular shape in plan view which integrally extends in horizontal directions (X-axis, Y-axis plane directions) orthogonal to an outside surface 3011 of the housing 301 which has a substantially cylindrical outer shape and supports on a non-contact basis the spindle 300 by air jetted inside thereof. Note that the collar section 32 is not limited to the mode of being formed to go around the outside surface 3011 of the housing 301; for example, a plurality of (for example, three) collar sections 32 may be formed at regular intervals in the circumferential direction of the outside surface 3011 of the housing 301 and in a substantially rectangular shape in plan view.

In the present embodiment, the rough grinding unit 3 depicted in FIG. 2 includes at least a holder 33 including a bottom plate 330 having a through-hole 3301 through which a lower portion of the spindle unit 30 is penetrated and a side plate 334 surrounding the spindle unit 30 with the collar section 32 supported by the bottom plate 330 and being connected to the bottom plate 330, and an inclination adjusting mechanism 34 which acts on the collar section 32 to adjust the inclination of the spindle unit 30.

For example, as depicted in FIG. 1, the holder 33 has a shape in which an upper-side portion of a bottomed cylinder is partly cut out obliquely downward. As illustrated in FIG. 2, the bottom plate 330 of the holder 33 is formed, for example, in a disk-like shape, and formed, in the center thereof, with the circular through-hole 3301. The through-hole 3301 has such a diameter that a lower portion of the spindle unit 30 can be passed therethrough. While a state in which the lower-side portion of the housing 301 of the spindle unit 30 is penetrating the through-hole 3301 is depicted in the illustrated example, a state in which only the spindle 300 projecting downward from the lower-side portion of the housing 301 is penetrating the through-hole 3301 may be adopted. The bottom plate 330 supports the collar section 32 and the spindle unit 30 through the inclination adjusting mechanism 34. An outside surface of a substantially cylindrical side plate 334 erected in the +Z direction from a region on the peripheral side of an upper surface of the bottom plate 330 is connected to the lift plate 203 of the rough grinding feeding means 20.

The inclination adjusting mechanism 34 includes a spring 342 interposed between a lower surface of the collar section 32 and an upper surface of the bottom plate 330; and an adjusting section 37 that acts to compress the spring 342 and adjusts the inclination of the spindle unit 30 by a compression amount of the spring 342.

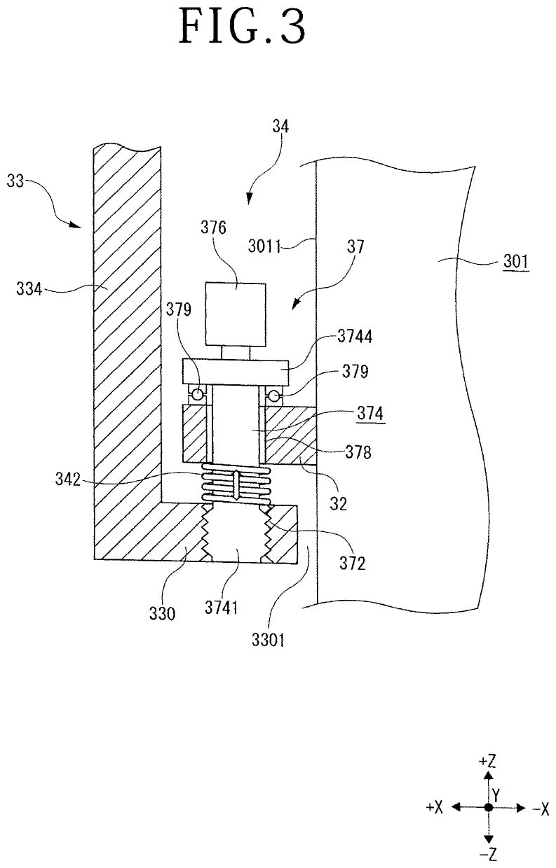

The structure of the adjusting section 37 depicted in FIGS. 2 and 3 (hereinafter referred to as the adjusting section 37 of the first embodiment) will be described. The adjusting section 37 includes female screws 372 formed in the bottom plate 330, a shaft 374 having on a lower end side a male screw 3741 for screw engagement with the female screw 372 and having a flange 3744 on an upper end side, a motor 376 for rotating the shaft 374, and a screw penetrating hole 378 which is formed in the collar section 32 and through which the shaft 374 is made to penetrate.

A plurality of (for example, three) female screws 372 are formed, for example, in a penetrating manner, with regular intervals (for example, intervals of 120 degrees) in the circumferential direction of the bottom plate 330. In each region of the collar section 32 facing the female screws 372 in the Z-axis direction, the screw penetrating hole 378 is formed in a penetrating manner in the thickness direction.

The inside diameter of an opening in the spring 342 is set to be larger than the diameters of the female screws 372, the screw penetrating hole 378, and the shaft 374, and, in a state in which the centers of the female screws 372, the center of the screw penetrating hole 378, and the center of the spring 342 substantially coincide with one another, a lower end side of the spring 342 is fixed to an upper surface of the bottom plate 330, and an upper end side of the spring 342 is fixed to a lower surface of the collar section 32. Note that the spring 342 may be of a spirally wound type or may be configured by stacking a plurality of annular coned disk springs.

The shaft 374 extending in the Z-axis direction in a T shape in plan view has the male screw 3741 on the lower end side in screw engagement with the female screw 372, in a state of penetrating the screw penetrating hole 378 and the opening of the spring 342. The motor 376 is connected to the upper end side of the shaft 374 through a coupling or the like.

Between a lower surface of the flange 3744 formed, for example, by radially enlarging in a circular shape on the upper end side of the shaft 374 and an upper surface of the collar section 32, there is disposed a bearing 379 which supports, by an upper surface of the collar section 32 and in a rotatable manner, the flange 3744 of the shaft 374 penetrating the screw penetrating hole 378 of the collar section 32 and having the male screw 3741 screw engaged with the female screw 372. While the bearing 379 illustrated is a thrust ball bearing, it may be an angular bearing or a roller bearing. Note that, while three adjusting sections 37 are disposed in the circumferential direction of the bottom plate 330 in the present embodiment, two adjusting sections 37 may be provided in addition to one fixed pole, or four or more adjusting sections 37 may be provided.

As illustrated in FIG. 1, the processing apparatus 1 includes a control unit 9 capable of controlling each component of the processing apparatus 1 described above. The control unit 9 including a central processing unit (CPU) and a storage element such as a memory or the like is electrically connected to the rough grinding feeding means 20, the rough grinding unit 3, the turntable 59, and the like, and, under the control of the control unit 9, the grinding feeding operation of the rough grinding unit 3 by the rough grinding feeding means 20, the rotating operation of the rough grinding wheel 304 of the rough grinding unit 3, a positioning operation of the holding unit 50 relative to the rough grinding wheel 304 by the turntable 59, and the like are controlled.

The motor 376 of the adjusting section 37 depicted in FIG. 2 is electrically connected to the control unit 9. The control unit 9 includes a rotation control section 91 which includes, for example, a microcontroller, a motor driver, and the like and supplies the motor 376 with a predetermined amount of an operation signal for rotationally driving the motor 376. The rotation control section 91 identifies the rotating direction of the motor 376, to recognize whether the shaft 374 is being lowered, or being raised, relative to the holder 33, thereby recognizing whether or not the spring 342 is being compressed. In addition, the rotation control section 91 identifies the rotational speed of the motor 376, to recognize a moving amount (a lowering amount) of the shaft 374, thereby recognizing a compression amount of the spring 342.

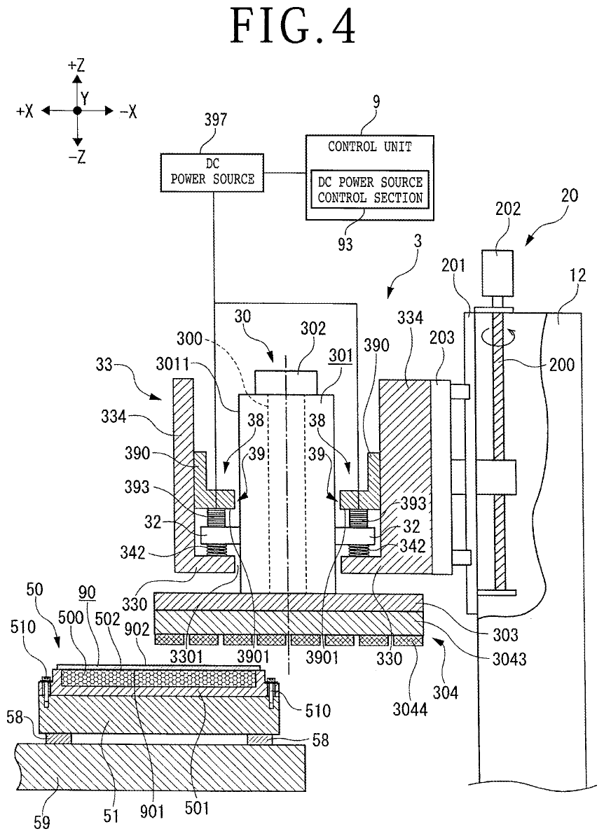

The rough grinding unit 3 may include an inclination adjusting mechanism 38 depicted in FIG. 4, in place of the inclination adjusting mechanism 34. The inclination adjusting mechanism 38 includes the spring 342 interposed between a lower surface of the collar section 32 and an upper surface of the bottom plate 330; and an adjusting section 39 of a second embodiment that acts to compress the spring 342 and adjusts the inclination of the spindle unit 30 by a compression amount of the spring 342.

The adjusting section 39 of the second embodiment includes support plates 390 that are disposed at an inner wall of the side plate 334 and that have support surfaces 3901 facing an upper surface of the collar section 32; and piezoelectric actuators 393 disposed between the support surface 3901 and an upper surface of the collar section 32.

A plurality of (for example, three) springs 342 are disposed between an upper surface of the bottom plate 330 and a lower surface of the collar section 32 with regular intervals (for example, intervals of 120 degrees) in the circumferential direction. Three support plates 390 are formed, for example, in an L shape in sectional view, and are disposed at an inner wall of the side plate 334 so as to be located directly above the springs 342. Note that the support plate 390 may be one support plate in the shape of a bottomed cylinder such that the support plate 390 goes round the inner wall of the side plate 334.

The piezoelectric actuator 393 including a piezoelectric ceramic or the like and extending in the Z-axis direction is, for example, a stacked type piezoelectric actuator, has an upper end fixed to the support surface 3901 as a lower surface of the support plate 390, and has a lower end fixed to an upper surface of the collar section 32. The three piezoelectric actuators 393 are located respectively on the upper side of the three springs 342. The displacing directions of the piezoelectric actuators 393 are in the Z-axis direction.

Each of the piezoelectric actuators 393 is supplied with electric power from a direct-current (DC) power source 397, and an appropriate voltage is applied thereon. The control unit 9 includes a DC power source control section 93, which sends an appropriate electric signal to the DC power source 397 and can thereby control the operation of the DC power source 397. Under the control of the DC power source 397 by the DC power source control section 93, the DC power source 397 applies any desired voltage to the piezoelectric actuator 393, whereby the piezoelectric actuator 393 is, for example, extended by a predetermined length in the −Z direction by a reverse voltage effect, resulting in that the DC power source control section 93 can recognize a contraction amount of the spring 342 pressed downward by the collar section 32.

Note that a pneumatic actuator may be used in place of the piezoelectric actuator 393. In addition, while the three adjusting sections 39 are disposed in the circumferential direction of the bottom plate 330 in the present embodiment, two adjusting sections 39 may be provided in addition to one fixed column, or four or more adjusting sections 39 may be provided.

A second column 13 is erected on a rear side of an upper side of the second apparatus base 11 depicted in FIG. 1, and finish grinding feeding means 21 is disposed on a front side of the second column 13. The finish grinding feeding means 21 is configured similarly to the rough grinding feeding means 20, and can put the finish grinding unit 31 into grinding feeding in the Z-axis direction. The finish grinding unit 31 includes finish grinding grindstones 3145 in which relatively small abrasive grains are contained, while the other configurations are substantially similar to those of the rough grinding unit 3, and includes the spindle unit 30, the inclination adjusting mechanism 34 for adjusting the inclination of the spindle unit 30, and the like.

A third column 14 is erected in line with the second column 13 on the rear side of the upper side of the second apparatus base 11, and, for example, X-axis moving means 48 capable of moving the polishing unit 4 in face directions (X-axis direction) of the workpiece 90 during polishing is disposed on the front side of the third column 14. The X-axis moving means 48 disposed on the front side of the third column 14 includes a ball screw 480 having an axis in the X-axis direction, a pair of guide rails 481 disposed in parallel to the ball screw 480, a motor 482 that is connected to the ball screw 480 and that rotates the ball screw 480, and a movable plate 483 having therein a nut screw engaged with the ball screw 480 and having side portions thereof in sliding contact with the guide rails 481; when the motor 482 rotates the ball screw 480, the movable plate 483 is moved in the X-axis direction while being guided by the guide rails 481, and the polishing unit 4 disposed on the movable plate 483 through polishing feeding means 47 is also moved in the X-axis direction. During polishing (in the present embodiment, for example, during dry polishing), a back surface 902 as a surface to be polished of the workpiece 90 may be formed with a stripe pattern, which may cause lowering in die strength of the workpiece 90. In view of this, during polishing, the polishing unit 4 may be reciprocally moved in the X-axis direction, and the polishing pad 44 may be slid in the X-axis direction on the back surface 902 of the workpiece 90, thereby preventing the die strength of the workpiece 90 from being lowered.

The polishing feeding means 47 that lifts the polishing unit 4 depicted in FIG. 1 upward and downward in the Z-axis direction perpendicular to the holding surface 502 of the holding unit 50 includes a ball screw 470 having an axis in the vertical direction, a pair of guide rails 471 disposed in parallel to the ball screw 470, a motor 472 that is connected to the ball screw 470 and that rotates the ball screw 470, and a lift plate 473 having therein a nut screw engaged with the ball screw 470 and having side portions in sliding contact with the guide rails 471; when the motor 472 rotates the ball screw 470, the lift plate 473 is moved in the Z-axis direction while being guided by the guide rails 471, and the polishing unit 4 supported by a holder 45 is also moved in the Z-axis direction.

The polishing unit 4 includes, for example, a spindle unit 40 configured substantially similarly to the spindle unit 30 and is different from the rough grinding unit 3 in that the processing tool mounted to a lower surface of a mount 43 connected to a lower end surface of a spindle 400 is a polishing pad 44. The polishing unit 4 is substantially similar to the rough grinding unit 3 in including the holder 45 and the inclination adjusting mechanism 34 or the like.

The circular polishing pad 44 detachably mounted to a lower surface of the mount 43 through an unillustrated platen includes, for example, a nonwoven fabric such as felt. The diameter of the polishing pad 44 is comparable to the diameter of the mount 43, and is, for example, larger than the diameter of the holding unit 50. Note that the polishing pad 44 may have abrasive grains adhered by an adhesive.

The polishing unit 4 supplies a slurry through the spindle unit 40 to the contact part between the workpiece 90 and the polishing pad 44, or chemical mechanical polishing (CMP) in which slurry jetted from an unillustrated external nozzle is supplied to the contact part between the workpiece 90 and the polishing pad 44 may be conducted or dry polishing may be applied to the workpiece 90.

A case of griding and polishing the workpiece 90 by use of the processing apparatus 1 depicted in FIG. 1 will be described below.

First, the turntable 59 illustrated in FIG. 1 is rotated, whereby the holding unit 50 in a state in which the workpiece 90 is not mounted thereon is rotated clockwise as viewed from the +Z direction side, and the holding unit 50 is moved to the vicinity of the loading arm 1540. In other words, the holding unit 50 positioned in the workpiece conveying-in/out area 573 is put into a state of being exposed to the exterior from the case cover 57. Then, the robot 155 takes out one sheet of workpiece 90 from the first cassette 1500, and moves the workpiece 90 to the temporary placing region 152.

After the center position of the workpiece 90 on the temporary placing region 152 is detected by the center position detecting means 153, the loading arm 1540 conveys the workpiece 90 onto the holding unit 50, and places the workpiece 90 on the holding surface 502 of the holding unit 50 such that the center of the holding surface 502 of the holding unit 50 and the center of the workpiece 90 substantially coincide with each other. Then, the unillustrated suction source is operated, whereby the workpiece 90 is held under suction on the holding surface 502 of the holding unit 50 in a state in which the back surface 902 of the workpiece 90 is exposed to the upper side. The workpiece 90 is put into a state of being held under suction along the holding surface 502 which is an extremely gentle conical surface.

After the workpiece 90 is held under suction by the holding unit 50, the turntable 59 depicted in FIG. 1 is put into revolution, and the holding unit 50 holding the workpiece 90 is positioned into a predetermined position in the case cover 57, in other words, into a position on a lower side of the rough grinding unit 3 depicted in FIG. 2. This positioning is performed in such a manner that the rotational center of the rough grinding grindstones 3044 of the rough grinding unit 3 is deviated by a predetermined distance in a horizontal direction from the rotational center of the workpiece 90, and that the rotational locus of the rough grinding grindstones 3044 passes through the rotational center of the workpiece 90.

Then, in the processing apparatus 1 according to the present invention, the inclination on the rough grinding unit 3 side is adjusted, whereby the back surface 902 of the workpiece 90 held under suction along the holding surface 502 which is a conical surface is set, for example, substantially parallel to the lower surfaces of the rough grinding grindstones 3044.

Specifically, for example, the motors 376 of two adjusting sections 37 depicted in FIG. 2 are supplied with an operation signal from the rotation control section 91 of the control unit 9, whereas the motor 376 of the remaining one adjusting section 37 is not supplied with an operation signal, whereby the two motors 376 rotate the two shafts 374. The shaft 374 is rotated smoothly relative to the collar section 32 by the bearing 379 disposed at the upper surface of the collar section 32, the male screw 3741 is gradually screw engaged with the female screw 372 formed in the bottom plate 330 in a fixed state, the shaft 374 is lowered, and the spindle unit 30 as a whole is gradually inclined such as to be lowered toward the viewer's side of the paper surface by the collar section 32 pressed downward by the flange 3744 with the bearing 379 interposed therebetween. In other words, in the present embodiment, in a state in which the shaft 374 of the one adjusting section 37 that is not illustrated and that is on the depth side of the paper surface is not lowered, the two adjusting sections 37 on the viewer's side of the paper surface are lowered, whereby the spindle unit 30 as a whole is gradually inclined so as to be lowered toward the viewer's side of the paper surface. In this state, the spring 342 is gradually compressed by a lower surface of the collar section 32 and an upper surface of the bottom plate 330.

Then, the rotation control section 91 identifies the rotational speed of the motor 376 and recognizes the moving amount (lowering amount) of the shaft 374, whereby it is possible, while recognizing the compression amount of the spring 342, to compress the spring 342 by a predetermined amount to set the flat lower surfaces of the rough grinding grindstones 3044 parallel to the back surface 902 of the workpiece 90 held under suction along the holding surface 502 which is an extremely gentle conical surface to such an extent as not to be visually distinguishable by the naked eye.

In the case where the rough grinding unit 3 includes the inclination adjusting mechanism 38 depicted in FIG. 4 in place of the inclination adjusting mechanism 34, under the control of the DC power source 397 by the DC power source control section 93 of the control unit 9, for example, the piezoelectric actuators 393 of the two adjusting section 39 depicted in FIG. 4 are supplied with electric power from the DC power source 397, whereas the piezoelectric actuator 393 of the remaining one adjusting section 39 is not supplied with electric power, so that the two piezoelectric actuators 393 on the viewer's side of the paper surface that are attached to the fixed support plate 390 are extended in the −Z direction. Then, the spindle unit 30 as a whole is gradually inclined so as to be lowered toward the viewer's side of the paper surface by the collar section 32 pressed downward by the piezoelectric actuators 393. In other words, in the present embodiment, in a state in which the piezoelectric actuator 393 of the one adjusting section 39 that is not illustrated and that is on the depth side of the paper surface is not extended, the piezoelectric actuators 393 of the two adjusting sections 39 on the viewer's side of the paper surface are extended, whereby the spindle unit 30 as a whole is gradually inclined so as to be lowered toward the viewer's side of the paper surface. In this state, the spring 342 is gradually compressed by the lower surface of the collar section 32 and the upper surface of the bottom plate 330.

The DC power source control section 93 identifies the amount of electric power supplied to the piezoelectric actuators 393 to recognize the extension amounts of the piezoelectric actuators 393, in other words, the compression amount of the spring 342, and, while doing so, can compress the spring 342 by a predetermined amount to thereby set the flat lower surfaces of the rough grinding grindstones 3044 parallel to the back surface 902 of the workpiece 90 held under suction along the holding surface 502 which is a conical surface.

After inclination adjustment of the rough grinding unit 3 is properly conducted by the inclination adjusting mechanism 34 depicted in FIG. 2 or the inclination adjusting mechanism 38 depicted in FIG. 4, for example, the grinding motor 302 depicted in FIGS. 1 and 2 rotates the spindle 300, which is attended by rotation of the rough grinding wheel 304 at a predetermined rotational speed. The rough grinding unit 3 is fed in the −Z direction by the rough grinding feeding means 20, and enters through an unillustrated circular opening formed in the top plate 576 of the case cover 57, and the rough grinding grindstones 3044 make contact with the back surface 902 of the workpiece 90, whereby grinding is performed. During grinding, the workpiece 90 is also rotated attendant on the rotation of the holding unit 50, and, thus, the rough grinding grindstones 3044 grind the whole area of the back surface 902 of the workpiece 90. In addition, grinding water is supplied through the spindle 300 to the contact parts between the rough grinding grindstones 3044 and the back surface 902 of the workpiece 90, and cooling of the contact parts and cleaning-away of fine grinding swarf by the grinding water are performed.

While measurement of the thickness of the workpiece 90 is performed by unillustrated thickness measuring means, the workpiece 90 is roughly ground to a desired thickness, and then the rough grinding feeding means 20 raises the rough grinding unit 3 in the +Z direction, to space the rough grinding unit 3 from the workpiece 90.

Next, the turntable 59 is put into revolution, and the holding unit 50 holding the workpiece 90 after rough grinding is positioned into a predetermined position in the case cover 57, in other words, into a position on a lower side of the finish grinding unit 31. This positioning is conducted in such a manner that the rotational center of the finish grinding grindstones 3145 of the finish grinding unit 31 is deviated by a predetermined distance in a horizontal direction from the rotational center of the workpiece 90 and that the rotational locus of the finish grinding grindstones 3145 passes through the rotational center of the workpiece 90. In addition, inclination adjustment for the finish grinding unit 31 is conducted substantially similarly to that for the rough grinding unit 3. Then, finish grinding is conducted with supply of grinding water, substantially similarly to rough grinding, whereby the workpiece 90 is ground to a finished thickness.

Thereafter, the finish grinding unit 31 is spaced away from the workpiece 90, further, the turntable 59 is rotated, and the holding unit 50 holding the workpiece 90 ground to the finished thickness is positioned into a predetermined position in the case cover 57, in other words, into a position on a lower side of the polishing unit 4. This positioning is conducted in such a manner that, for example, during polishing, the polishing pad 44 normally makes contact with the whole area of the back surface 902 of the workpiece 90, in other words, that the polishing pad 44 covers the back surface 902 of the workpiece 90 held by the holding unit 50. In addition, inclination adjustment for the polishing pad 44 is conducted substantially similarly to that performed for the rough grinding unit 3.

Next, the polishing unit 4 is fed in the −Z direction by the polishing feeding means 47 depicted in FIG. 1, and enters into the case cover 57, and the polishing pad 44 being rotated makes contact with the back surface 902 of the workpiece 90, whereby, for example, dry polishing in the present embodiment is performed. With the polishing pad 44 reciprocally moved in the X-axis direction, the back surface 902 of the workpiece 90 is polished for a predetermined period of time to be mirror finished, and the die strength of the workpiece 90 is enhanced, after which the polishing unit 4 is raised by the polishing feeding means 47 to space the polishing pad 44 away from the workpiece 90.

As described above, in the processing apparatus 1 according to the present invention, the spindle unit 30 includes the collar section 32 extending from the outside surface in a horizontal direction orthogonal to the outside surface; for example, the rough grinding unit 3 includes the bottom plate 330 having the through-hole 3301 through which a lower portion of the spindle unit 30 penetrates, the holder 33 including the side plate 334 surrounding the spindle unit 30 with the collar section 32 supported by the bottom plate 330 and being connected to the bottom plate 330, and the inclination adjusting mechanism 34 that acts on the collar section 32 and adjusts the inclination of the spindle unit 30; and the inclination adjusting mechanism 34 includes the spring 342 interposed between the lower surface of the collar section 32 and the upper surface of the bottom plate 330 and the adjusting section 37 that acts to compress the spring 342 and adjusts the inclination of the spindle unit 30 by a compression amount of the spring 342, whereby the need to change the inclination of the holding unit 50 is eliminated, and the need to form the turntable 59 with a cavity for disposing the inclination adjusting mechanism is eliminated. Thus, when the workpiece 90 is processed under a high load, the turntable 59 on which the holding unit 50 is disposed is less liable to warp, and the workpiece 90 is easily processed to be flat. In addition, with the weight of the rough grinding unit 3 received by the spring 342, it becomes possible to reduce the sizes of the motor 376 as a drive source for rotating the shaft 374 and the grinding motor 302 as a drive source for rotating the spindle 300.

Note that a cooling passage for passing cooling water may be provided in the inside of the collar section 32 or in the inside of the support plate 390, to keep the piezoelectric actuators 393 at a predetermined temperature. In addition, the grinding load or polishing load may be measured by use of the piezoelectric actuator 393.

In addition, a pulsed voltage for repeating ON and OFF of a predetermined voltage may be supplied to the piezoelectric actuators 393, to finely vibrate the rough grinding grindstones 3044, thereby strengthening the grinding force of the rough grinding grindstones 3044. In addition, a vibration measuring instrument for measuring grinding vibration may be provided, and, according to the frequency and amplitude measured by the vibration measuring instrument, a DC power source may be controlled so as to repeat extension and compression of the piezoelectric actuators 393 with reverse amplitude at the same frequency, thereby eliminating vibration generated by grinding.

Note that the processing apparatus 1 according to the present invention is not limited to the above embodiment, the shape and the like of each configuration of the processing apparatus 1 illustrated in the attached drawings are not limited by the illustrated ones, and appropriate modifications are possible within such ranges that the effects of the present invention can be exhibited.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising:
a processing unit in which a spindle unit supporting, in a rotatable manner, a spindle having a processing tool that is mounted to a tip thereof and that extends in the vertical direction is mounted; and
a chuck table that holds a workpiece,
wherein the spindle unit has a collar section extending from an outside surface in a horizontal direction orthogonal to the outside surface,
the processing unit includes a holder including a bottom plate having a through-hole through which a lower portion of the spindle unit penetrates and a side plate that surrounds the spindle unit with the collar section supported by the bottom plate and that is connected to the bottom plate, and an inclination adjusting mechanism that acts on the collar section to adjust the inclination of the spindle unit, and
the inclination adjusting mechanism includes a spring interposed between a lower surface of the collar section and an upper surface of the bottom plate and an adjusting section that acts to compress the spring and adjusts the inclination of the spindle unit by a compression amount of the spring.

2. The processing apparatus according to claim 1,
wherein the adjusting section includes a female screw formed in the bottom plate, a shaft having a male screw for screw engagement with the female screw on a lower end side and having a flange on an upper end side, a motor that rotates the shaft, and a threaded through-hole that is formed in the collar section and permits the shaft to penetrate therethrough, and
the processing apparatus includes a bearing that supports, in a rotatable manner, the flange of the shaft penetrating the threaded through-hole in the collar section and having the male screw in screw engagement with the female screw, by an upper surface of the collar section.

3. The processing apparatus according to claim 1, wherein the adjusting section includes a support plate that is disposed on an inner wall of the side plate and that has a support surface facing an upper surface of the collar section and a piezoelectric actuator disposed between the support surface and the upper surface of the collar section.
